(19) United States
(12) Patent Application Publication
(10) Pub. No.: US 2003/0177437 A1
(43) Pub. Date: Sep. 18, 2003

(54) Erroneous packet data convergence protocol data unit handling scheme in a wireless communication system

(76) Inventor: Frank Chih-Hsiang Wu, Taipei Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/325,948

(22) Filed: Dec. 23, 2002

Related U.S. Application Data
(60) Provisional application No. 60/364,589, filed on Mar. 18, 2002.

(51) Int. Cl. H03M 13/00

(52) U.S. Cl. 714/776

(57) ABSTRACT

The present invention provides a procedure for confirming data transmission which efficiently eliminates problems existing in lossless SRNS Relocation and PDCP Sequence Number synchronisation and improves wireless communication system performance. A PDCP SeqNum PDU is sent when the PDCP sender thinks it needs to send it. If the PDCP receiver is aware of the PDCP sender should not send a PDCP SeqNum PDU but receives a PDCP SeqNum PDU, the PDCP receiver shall not use the sequence number in the PDCP SeqNum PDU to set UL/DL Receive SN. A PDCP SeqNum PDU is sent after, an RLC reset procedure, and/or an RLC re-establishment not caused by a SRNS Relocation, and/or next expected UL/DL receive PDCP sequence number is considered invalid after SRNS Relocation. Therefore, if a PDCP SeqNum PDU is received but not immediately after the above procedures, the sequence number in the PDCP SeqNum PDU should not be used to set UL/DL receive SN. The Data in PDCP SeqNum PDU may or may not be discarded. Therefore, the present invention provides a scheme for handling erroneous PDCP PDU's so that data is not lost and unnecessary synchronization procedures are not triggered. As a result radio resources are not wasted and system performance is improved.

### REFERENCE TO RELATED APPLICATION

This Patent Application is based upon Provisional Patent Application Serial No. 60/364,589, filed Mar. 18, 2002, entitled “Erroneous Packet Data Convergence Protocol Data Unit Handling Scheme in a Wireless Communication System.”

### BACKGROUND OF THE INVENTION

1. Field of the Invention

The present invention relates to a wireless communications protocol. More specifically, the present invention discloses a procedure for handling erroneous packet data convergence protocol data units.

2. Description of the Prior Art

Advancements in communication technologies have allowed new types of communication systems to be made possible. Such new types of communication systems have for the most part, permitted increased rates of data transmission as well as related amounts of data to be communicated in such new communication systems.

These advancements in communication technologies have allowed new types of radio communication systems to be introduced and popularization. Among these advancements has been the use of radio communication systems to form at least a part of the communication path so the use of conventional wirelines is reduced.

However, radio or wireless communication systems can be constrained by certain limitations. These limitations, such as bandwidth and error correction limitations, affect the overall wireless communication system performance. If a system is unable to handle or recover from different types of errors, the system performance is degraded. Depending upon the severity of such errors, the wireless communication system can be hampered or even rendered inoperable.

Therefore, there is need for an improved scheme for efficiently handling errors so that wireless communication system performance is improved.

### SUMMARY OF THE INVENTION

To achieve advantages and in order to overcome the disadvantages of the conventional method in accordance with the purpose of the invention as embodied and broadly described herein, the present invention provides a scheme for efficiently handling erroneous packet data convergence protocol (PDCP) protocol data unit (PDU) and thereby improves wireless communication system performance.

Packet Data Convergence Protocol (PDCP) is defined by the 3rd Generation Partnership Project (3GPP) specification 3GPP TS 25.323 V3.9.0 “Packet Data Convergence Protocol (PDCP) Specification”, which is included herein by reference. PDCP provides its services to the upper layers, e.g. IP and PPP. PDCP performs the following functions: header compression and decompression of IP data streams (e.g., TCP/IP and RTP/UDP/IP headers for IPv4 and IPv6) at the transmitting and receiving entity respectively, transfer of user data, and maintenance of PDCP sequence numbers for radio bearers that are configured to support lossless SRNS Relocation. PDCP uses the services provided by the Radio Link Control (RLC) sublayer.

Lossless SRNS Relocation is only applicable when an RLC is configured for in-sequence delivery and acknowledged mode (AM). The support of lossless SRNS Relocation is configured by upper layer. PDCP sequence numbering shall be applied when lossless SRNS Relocation is supported. PDCP Sequence Numbers serve to acknowledge previously transmitted PDCP service data units (SDU's) prior to relocation. The value of the PDCP sequence number ranges from 0 to 65535. The PDCP SN window size indicates the maximum number of PDCP SDU's, not confirmed to have been successfully transmitted to the peer entity by RLC layer, that can be numbered at any given time. The PDCP SN window size is configured by upper layers. PDCP sequence numbers are set to “0” when the PDCP entity is set-up for the first time.

The PDCP sequence number (SN) is used to number PDCP SDU's for radio bearers configured to support lossless SRNS relocation. The PDCP SN is usually not sent with PDCP PDU. Synchronization for PDCP sequence numbers between the PDCP sender and receiver is important. Lack of synchronization of PDCP sequence numbers between two PDCP entities causes problems such as PDCP PDU's loss.

For radio bearers that are configured to support lossless SRNS Relocation, the PDCP entity will do the following. If upper layer indicates to a PDCP entity that it should synchronise the PDCP SN following an RLC reset or RLC re-establishment not caused by a SRNS Relocation or if the user equipment (UE)/universal mobile telecommunications system terrestrial radio access network (UTRAN) PDCP entity receives an invalid next expected uplink (UL)/downlink (DL) receive PDCP sequence number from upper layer after relocation, the PDCP entity will trigger the PDCP SN synchronisation procedure by submitting one PDCP SeqNum PDU to lower layer, and/or consider that the synchronisation procedure is complete on confirmation by lower layer of the successful transmission of the PDCP SeqNum PDU.

In the UE/IUTRAN, the next expected UL/DL receive PDCP sequence number is considered invalid if its value is less than the send PDCP SN of the first transmitted but not yet acknowledged PDCP SDU or greater than that of the first unsent PDCP SDU.

On receiving a PDCP SeqNum PDU the UE PDCP entity should set the value of the DL receive PDCP sequence number to the value indicated in the PDCP SeqNum PDU. On receiving a PDCP SeqNum PDU, the UTRAN PDCP entity should set the value of the UL receive PDCP sequence number to the value indicated in the PDCP SeqNum PDU.

Typical handling of unknown, unforeseen and erroneous protocol data is as follows. For invalid PDU types, if a PDCP entity receives a PDCP PDU with a PDU type set to reserved it should discard the PDCP PDU.

If a PDCP entity is not configured for lossless SRNS Relocation and receives a PDCP SeqNum PDU, it should discard the PDCP SeqNum PDU.

For invalid packet identifier (PID) values, if a PDCP entity receives a PDCP PDU with a PID value that is not mapped with a valid packet type, it should discard the PDCP PDU.

The PDCP SeqNum PDU is used to convey a PDCP SDU sequence number and either data containing an uncompressed PDCP SDU or data that has been obtained from PDCP SDU after header compression.

The description above specifies actions that are taken while receiving a PDCP SeqNum PDU. However, this description is for general purpose so unexpected protocol errors may occur in some situations. In such cases, a PDCP Data PDU can be recognized as a PDCP SeqNum PDU mostly due to residual errors or if the PDCP sender is abnormal.

Therefore, there is need for an improved scheme for efficiently handling erroneous PDCP PDU's so that wireless communication system performance is improved.

Therefore, the present invention provides a scheme for handling erroneous PDCP PDU's so that data is not lost and unnecessary synchronization procedures are not triggered. As a result radio resources are not wasted and system performance is improved.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a diagram illustrating a format of the PDCP SeqNum PDU; and

FIG. 2 is a flowchart illustrating a scheme for handling erroneous PDCP PDU's according to an embodiment of the present invention.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

Packet Data Convergence Protocol (PDCP) is defined by the 3rd Generation Partnership Project (3GPP) specification 3GPP TS 25.323 V3.9.0 “Packet Data Convergence Protocol (PDCP) Specification”, which is included herein by reference. PDCP provides its services to the upper layers, e.g. IP and PPP. PDCP performs the following functions: header compression and decompression of IP data streams (e.g., TCP/IP and RTP/UDP/IP headers for IPv4 and IPv6) at the transmitting and receiving entity respectively, transfer of user data, and maintenance of PDCP sequence numbers for radio bearers that are configured to support lossless SRNS Relocation. PDCP uses the services provided by the Radio Link Control (RLC) sublayer.

Lossless SRNS Relocation is only applicable when an RLC is configured for in-sequence delivery and acknowledged mode (AM). The support of lossless SRNS Relocation is configured by upper layer. PDCP sequence numbering shall be applied when lossless SRNS Relocation is supported. PDCP Sequence Numbers serve to acknowledge previously transmitted PDCP service data units (SDU's) prior to relocation. The value of the PDCP sequence number ranges from 0 to 65535. The PDCP SN window size indicates the maximum number of PDCP SDU's, not confirmed to have been successfully transmitted to the peer entity by RLC layer, that can be numbered at any given time. The PDCP SN window size is configured by upper layers. PDCP sequence numbers are set to “0” when the PDCP entity is set-up for the first time.

The PDCP sequence number (SN) is used to number PDCP SDU's for radio bearers configured to support lossless SRNS relocation. The PDCP SN is usually not sent with PDCP PDU. Synchronization for PDCP sequence numbers between the PDCP sender and receiver is important. Lack of synchronization of PDCP sequence numbers between two PDCP entities causes problems such as PDCP PDU's loss.

For radio bearers that are configured to support lossless SRNS Relocation, the PDCP entity will do the following. If upper layer indicates to a PDCP entity that it should synchronise the PDCP SN following an RLC reset or RLC re-establishment not caused by a SRNS Relocation or if the user equipment (UE)/universal mobile telecommunications system terrestrial radio access network (UTRAN) PDCP entity receives an invalid next expected uplink (UL)/downlink (DL) receive PDCP sequence number from upper layer after relocation, the PDCP entity will trigger the PDCP SN synchronisation procedure by submitting one PDCP SeqNum PDU to lower layer, and/or consider that the synchronisation procedure is complete on confirmation by lower layer of the successful transmission of the PDCP SeqNum PDU.

In the UE/UTRAN, the next expected UL/DL receive PDCP sequence number is considered invalid if its value is less than the send PDCP SN of the first transmitted but not yet acknowledged PDCP SDU or greater than that of the first unsent PDCP SDU.

On receiving a PDCP SeqNum PDU the UE PDCP entity should set the value of the DL receive PDCP sequence number to the value indicated in the PDCP SeqNum PDU. On receiving a PDCP SeqNum PDU, the UTRAN PDCP entity should set the value of the UL receive PDCP sequence number to the value indicated in the PDCP SeqNum PDU.

Typical handling of unknown, unforeseen and erroneous protocol data is as follows. For invalid PDU types, if a PDCP entity receives a PDCP PDU with a PDU type set to reserved it should discard the PDCP PDU.

If a PDCP entity is not configured for lossless SRNS Relocation and receives a PDCP SeqNum PDU, it should discard the PDCP SeqNum PDU.

For invalid PID values, if a PDCP entity receives a PDCP PDU with a PID value that is not mapped with a valid packet type, it should discard the PDCP PDU.

The PDCP SeqNum PDU is used to convey a PDCP SDU sequence number and either data containing an uncompressed PDCP SDU or data that has been obtained from PDCP SDU after header compression.

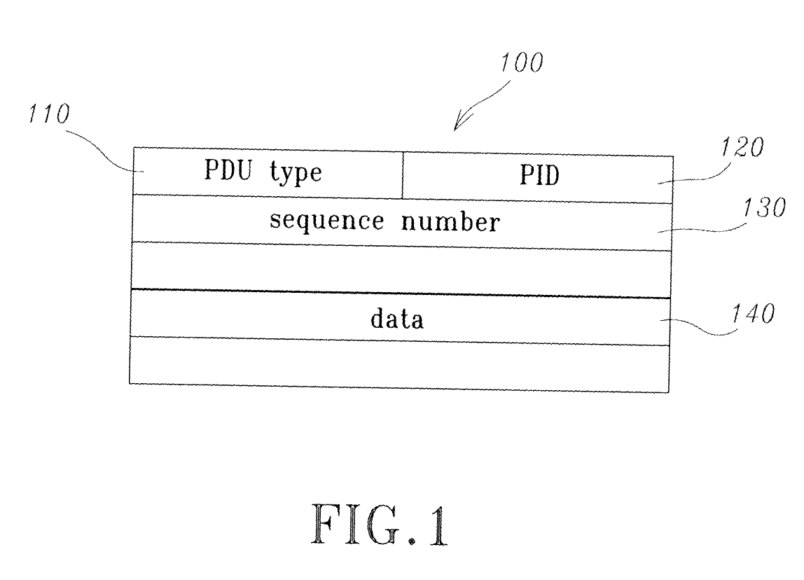

Refer to FIG. 1 which is a diagram illustrating a format of the PDCP SeqNum PDU.

The PDCP SeqNum PDU 100 comprises a PDU type 110, a packet identifier PID 120, sequence number 130, and data 140.

The description above specifies actions that are taken while receiving a PDCP SeqNum PDU. This description is for general purpose so unexpected protocol errors may occur in some situations. In such cases, a PDCP Data PDU can be recognized as a PDCP SeqNum PDU mostly due to residual errors or if the PDCP sender is abnormal. As an example, consider the following scenario.

Assume that the UE is the PDCP sender, UTRAN is the PDCP receiver, and the DL send PDCP sequence number equals the UL receive PDCP sequence number which equals 10. The UE sends a PDCP PDU and DL send PDCP sequence number equal to 11. The UTRAN receives it and recognizes it as a PDCP SeqNum PDU due to residual errors. Assume the sequence number in the received PDCP SeqNum PDU equals 15. Accordingly, the UTRAN sets the UL receive PDCP sequence number to 15. The UE continues to send 10 PDCP PDU's containing PDCP SDU's. Therefore, the DL send PDCP SN is 21. Now lossless SRNS relocation occurs.

Following is an example describing a situation where unexpected protocol errors can occur.

Continuing from the above scenario, the UTRAN only received one PDCP PDU and sends the next expected UL receive PDCP sequence number equal to 17 to the UE. The UE thinks that the UTRAN correctly received PDCP PDU's with SN from 12 to 16 and starts transmitting from PDCP PDU from SN equal to 17. Accordingly, PDCP PDU's with SN from 12 to 16 are lost. This loss of PDCP PDU's seriously degrades system performance.

Following is an example describing another situation where unexpected protocol errors can occur.

Continuing from the original scenario, the UTRAN received 10 PDCP PDU's and sends the next expected UL receive PDCP sequence number equal to 26 to the UE. This is an invalid next expected UL receive PDCP sequence number. Therefore, the UE starts transmitting by sending a PDCP SeqNum PDU containing retransmitted PDCP SDU and sequence number equal to 21. As a result an unnecessary PDCP SN synchronization procedure is triggered. This unnecessary synchronization procedure wastes radio resource thereby degrading system performance.

Therefore, there is need for an improved scheme for efficiently handling erroneous PDCP PDU's so that wireless communication system performance is improved.

Therefore, the present invention provides a scheme for handling erroneous PDCP PDU's so that data is not lost and unnecessary synchronization procedures are not triggered. As a result radio resources are not wasted and system performance is improved.

A PDCP SeqNum PDU is sent when the PDCP sender thinks it needs to send it. If the PDCP receiver is aware the PDCP sender should not send a PDCP SeqNum PDU but receives a PDCP SeqNum PDU, the PDCP receiver shall not use the sequence number in the PDCP SeqNum PDU to set UL/DL Receive SN. A PDCP SeqNum PDU is sent after, an RLC reset procedure, and/or an RLC re-establishment not caused by a SRNS Relocation, and/or if the next expected UL/DL receive PDCP sequence number is considered invalid after SRNS Relocation.

Therefore, if a PDCP SeqNum PDU is received but not immediately after the above procedures, the sequence number in the PDCP SeqNum PDU should not be used to set UL/DL receive SN. The Data in PDCP SeqNum PDU may or may not be discarded.

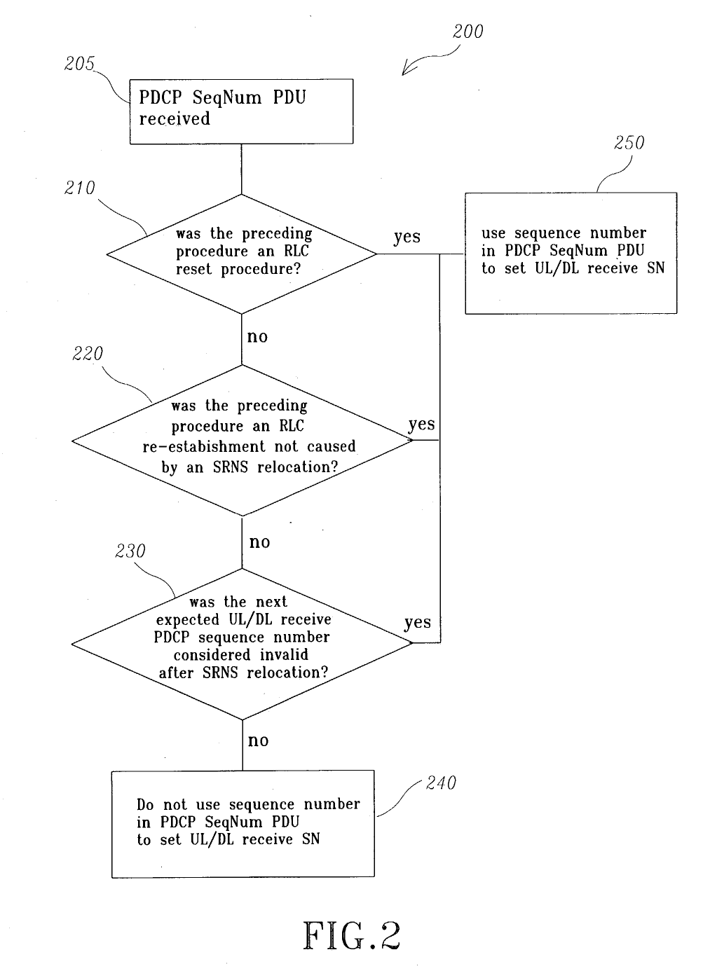

Refer to FIG. 2, which is a flowchart illustrating a scheme for handling erroneous PDCP PDU's according to an embodiment of the present invention.

The scheme 200 begins when a PDCP SeqNum PDU is received 205. In step 210, if the procedure immediately preceding was an RLC reset procedure, the sequence number in the PDCP SeqNum PDU is used to set the UL/DL receive SN in step 250. If not, in step 220, if the procedure immediately preceding was an RLC re-establishment not caused by SRNS Relocation, the sequence number in the PDCP SeqNum PDU is used to set the UL/DL receive SN in step 250. If not, in step 230, if the next expected UL/DL receive PDCP sequence number was considered invalid after SRNS relocation, the sequence number in the PDCP SeqNum PDU is used to set the UL/DL receive SN in step 250. If not, in step 240, the sequence number in the PDCP SeqNum PDU is not used to set the UL/DL receive SN.

Refer back to the original scenario described above. In the first example problem, since the preceding procedure was not an RLC reset procedure, and/or an RLC re-establishment not caused by a SRNS Relocation, and/or next expected UL/DL receive PDCP sequence number was not considered invalid after SRNS Relocation, the sequence number in the PDCP SeqNum PDU is not used to set the UL/DL receive SN. Therefore, PDCP PDU's are not lost and system performance is maintained.

Referring to the second example problem, since the preceding procedure was not an RLC reset procedure, and/or an RLC re-establishment not caused by a SRNS Relocation, and/or next expected UL/DL receive PDCP sequence number was not considered invalid after SRNS Relocation, the sequence number in the PDCP SeqNum PDU is not used to set the UL/DL receive SN. Therefore, unnecessary PDCP SN synchronization procedures are not triggered and system performance is preserved.

As shown above, there is need for an improved scheme for efficiently handling erroneous PDCP PDU's so that wireless communication system performance is improved.

Therefore, the present invention provides a scheme for handling erroneous PDCP PDU's so that data is not lost and unnecessary synchronization procedures are not triggered. As a result radio resources are not wasted and system performance is improved. By providing a procedure for confirming data transmission which efficiently eliminates problems existing in lossless SRNS Relocation and PDCP Sequence Number synchronisation, the present invention improves wireless communication system performance.

Note that the embodiment of the present invention illustrated in FIG. 2 is only one method for handling erroneous PDCP PDU's. In other embodiments, various other steps or methods are utilized for handling erroneous PDCP PDU's without deviating from the scope of the present invention of eliminating inappropriate handling of erroneous PDCP PDU's.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A method for handling erroneous packet data convergence protocol data units comprising:
receiving a packet data convergence protocol sequence number protocol data unit (PDCP SeqNum PDU) comprising a sequence number;
determining if a preceding procedure was a radio link control (RLC) reset procedure; and
setting or not setting a receive sequence number depending upon the preceding procedure.

2. The method for handling erroneous packet data convergence protocol data units of claim 1, wherein if the preceding procedure was an RLC reset procedure, the sequence number in the PDCP SeqNum PDU is used to set the receive sequence number.

3. The method for handling erroneous packet data convergence protocol data units of claim 2, wherein the receive sequence number is an uplink or downlink receive sequence number.

4. The method for handling erroneous packet data convergence protocol data units of claim 1, wherein, if the preceding procedure was not an RLC reset procedure, the sequence number in the PDCP SeqNum PDU is not used to set the receive sequence number.

5. The method for handling erroneous packet data convergence protocol data units of claim 4, wherein the receive sequence number is an uplink or downlink receive sequence number.

6. A method for handling erroneous packet data convergence protocol data units comprising:
receiving a packet data convergence protocol sequence number protocol data unit (PDCP SeqNum PDU) comprising a sequence number;
determining if a preceding procedure was an RLC re-establishment not caused by a SRNS Relocation; and
setting or not setting a receive sequence number depending upon the preceding procedure.

7. The method for handling erroneous packet data convergence protocol data units of claim 6, wherein if the preceding procedure was an RLC reestablishment not caused by a SRNS Relocation, the sequence number in the PDCP SeqNum PDU is used to set the receive sequence number.

8. The method for handling erroneous packet data convergence protocol data units of claim 7, wherein the receive sequence number is an uplink or downlink receive sequence number.

9. The method for handling erroneous packet data convergence protocol data units of claim 6, wherein if the preceding procedure was not an RLC reestablishment not caused by a SRNS Relocation, the sequence number in the PDCP SeqNum PDU is not used to set the receive sequence number.

10. The method for handling erroneous packet data convergence protocol data units of claim 9, wherein the receive sequence number is an uplink or downlink receive sequence number.

11. A method for handling erroneous packet data convergence protocol data units comprising:
receiving a packet data convergence protocol sequence number protocol data unit (PDCP SeqNum PDU) comprising a sequence number;
determining if the preceding procedure was a SRNS Relocation procedure; and
setting or not setting a receive sequence number depending upon the preceding procedure.

12. The method for handling erroneous packet data convergence protocol data units of claim 11, wherein if the preceding procedure was a SRNS Relocation procedure, the sequence number in the PDCP SeqNum PDU is used to set the receive sequence number.

13. The method for handling erroneous packet data convergence protocol data units of claim 12, wherein the receive sequence number is an uplink or downlink receive sequence number.

14. The method for handling erroneous packet data convergence protocol data units of claim 11, wherein if the preceding procedure was not a SRNS Relocation procedure, the sequence number in the PDCP SeqNum PDU is not used to set the receive sequence number.

15. The method for handling erroneous packet data convergence protocol data units of claim 14, wherein the receive sequence number is an uplink or downlink receive sequence number.

16. A method for handling erroneous packet data convergence protocol data units comprising:
receiving a packet data convergence protocol sequence number protocol data unit (PDCP SeqNum PDU) comprising a sequence number; and
determining if a preceding procedure was a radio link control (RLC) reset procedure;
determining if a preceding procedure was an RLC re-establishment not caused by a SRNS Relocation;
determining if a preceding precedure was a SRNS Relocation procedure; and
setting or not setting a receive sequence number depending upon the preceding procedure.

17. The method for handling erroneous packet data convergence protocol data units of claim 16, wherein if the preceding procedure was an RLC reset procedure or an RLC re-establishment not caused by a SRNS Relocation, or a SRNS Relocation procedure, the sequence number in the PDCP SeqNum PDU is used to set the receive sequence number.

18. The method for handling erroneous packet data convergence protocol data units of claim 17, wherein the receive sequence number is an uplink or downlink receive sequence number.

19. The method for handling erroneous packet data convergence protocol data units of claim 16, wherein if the preceding procedure was not an RLC reset procedure nor an RLC re-establishment not caused by a SRNS Relocation, and a SRNS Relocation procedure, the sequence number in the PDCP SeqNum PDU is not used to set the receive sequence number.

20. The method for handling erroneous packet data convergence protocol data units of claim 19, wherein the receive sequence number is an uplink or downlink receive sequence number.
